(19) United States
(12) Patent Application Publication
(10) Pub. No.: US 2010/0212728 A1
(43) Pub. Date: Aug. 26, 2010

(54) Diode and Photovoltaic Device Using Carbon Nanostructure

(76) Inventors: Masaru Hori, Aichi (JP); Yutaka Tokuda, Aichi (JP); Hiroyuki Kano, Aichi (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 11/992,751

(22) PCT Filed: Sep. 28, 2006
(86) PCT No.: PCT/JP2006/319368

§ 371 Date: May 11, 2010

(30) Foreign Application Priority Data
Sep. 29, 2005 (JP) 2005-285662
Sep. 29, 2005 (JP) 2005-285668

(51) Int. Cl. H01L 27/142; H01L 29/66

(52) U.S. Cl. 136/255; 257/9; 257/E27.123; 257/E29.168; 977/742

(57) ABSTRACT

To provide an electronic device employing a carbon nanostructure and exhibiting novel characteristics.

n-Conduction-type carbon nanowalls 81 were formed on an n-conduction-type silicon substrate 80. Subsequently, p-conduction-type carbon nanowalls 82 were grown so as to cover the surfaces of the n-conduction-type carbon nanowalls 81. Gold was deposited on the end surfaces of the p-conduction-type carbon nanowalls 82 through EB deposition, to thereby form a first electrode 85. Separately, gold was deposited on the bottom surface of the n-conduction-type silicon substrate 80 through EB deposition, to thereby form a second electrode 86. Thus, there was formed a diode having a pn junction between the n-conduction-type carbon nanowalls 81 and the p-conduction-type carbon nanowalls 82.

### TECHNICAL FIELD

The present invention relates to a diode or photovoltaic device including a carbon nano-scale structure (hereinafter may be referred to as a “carbon nanostructure”).

### BACKGROUND ART

There have been known carbon nanostructures, which are formed mainly of carbon and have a predetermined microstructure. Examples of such carbon nanostructures include fullerenes, carbon nanotubes, and carbon nanowalls. Patent Document 1 given below discloses a carbon nanostructure which is called “carbon nanowalls.” According to Patent Document 1, carbon nanowalls are formed on a nickel-iron-catalyst-coated sapphire substrate through, for example, application of microwaves to a mixture of CH₄ and H₂. Patent Document 2 given below discloses a method for forming carbon nanowalls of high quality.

### Patent Document 1: Specification of US Patent Application No. 2003/0129305

### Patent Document 2: PCT Publication WO 2005/021430 A1

### DISCLOSURE OF THE INVENTION

### Problems to be Solved by the Invention

Carbon nanotubes or carbon nanowalls have been envisaged for application to fuel cells and electronic devices such as field emission devices. However, electrical properties of such carbon nanostructures have not yet been elucidated.

The present inventors have conducted studies on the voltage-current characteristics of a structure having a predetermined junction formed of a carbon nanostructure, and have found that the structure exhibits rectification property or photovoltaic property.

The present invention has been accomplished on the basis of this finding. Thus, an object of the present invention is to realize a diode or photovoltaic device including a carbon nanostructure. No relevant prior art exists for the present invention.

### Means for Solving the Problems

The present invention provides, in claim 1, a diode comprising a p-conduction-type semiconductor, and an n-conduction-type carbon nanostructure grown on the p-conduction-type semiconductor.

According to the above aspect of the present invention, a pn junction is formed in the diode between the p-conduction-type semiconductor and the n-conduction-type carbon nanostructure.

The p-conduction-type semiconductor may be made of a desired semiconductor such as silicon, a group III-V compound semiconductor (e.g., GaAs), or a group III nitride semiconductor. The p-conduction-type semiconductor may be in a bulk form, or a p-conduction-type region formed through doping of a partial region of a substrate with an acceptor impurity.

The present invention provides, in claim 2, a diode as described above, which further comprises a first electrode connected to the upper end surface of the n-conduction-type carbon nanostructure, and a second electrode connected to the p-conduction-type semiconductor. The first electrode may be connected directly to the n-conduction-type carbon nanostructure, or an electrically conductive layer may be provided therebetween. The second electrode may be connected directly to the p-conduction-type semiconductor, or an electrically conductive layer may be provided therebetween.

The present invention provides, in claim 3, a diode comprising an n-conduction-type carbon nanostructure, and a p-conduction-type carbon nanostructure formed on a surface of the n-conduction-type carbon nanostructure.

According to the above aspect of the present invention, a pn junction is formed in the diode between the n-conduction-type carbon nanostructure, and the p-conduction-type carbon nanostructure formed on a surface of the n-conduction-type carbon nanostructure.

In the characteristic pn junction of the present invention, the n-conduction-type carbon nanostructure may be supported by any member.

When the n-conduction-type carbon nanostructure is grown on a substrate, no particular limitation is imposed on the substrate, and a desired substrate (e.g., a semiconductor substrate, a glass substrate, or a metal substrate) may be employed. The substrate employed may have insulating or electrically conductive property. The n-conduction-type carbon nanostructure may be formed on an electrically conductive diffusion region on a substrate, or may be formed on an electrically conductive material (e.g., a metal) provided on an insulating substrate.

The present invention provides, in claim 4, a diode as described in claim 3, wherein the n-conduction-type carbon nanostructure is formed on a substrate, and the diode further comprises a first electrode connected to the upper end surface of the p-conduction-type carbon nanostructure, and a second electrode connected to the n-conduction-type carbon nanostructure.

According to the above aspect of the present invention, the n-conduction-type carbon nanostructure is grown on a substrate; the first electrode is provided on the p-conduction-type carbon nanostructure; and the second electrode is connected to the n-conduction-type carbon nanostructure.

Similar to the case of claim 2 according to the present invention, the first electrode may be connected directly to the p-conduction-type carbon nanostructure, or an electrically conductive layer may be provided therebetween; and the second electrode may be connected directly to the n-conduction-type semiconductor, or an electrically conductive layer may be provided therebetween.

The present invention provides, in claim 5, a diode as described in claim 4, wherein the substrate is the n-conduction-type semiconductor, and the second electrode is formed on the substrate.

The present invention provides, in claim 6, a diode as described in any one of claims 1 to 5, wherein the p-conduction-type carbon nanostructure is a carbon nanostructure having a surface terminated by fluorine atoms.

According to the above aspect of the present invention, the p-conduction-type carbon nanostructure is formed, with terminating carbon atoms of a surface of a carbon nanostructure by fluorine atoms.

The present invention provides, in claim 7, a diode comprising an n-conduction-type carbon nanostructure, and a first electrode formed on the upper end surface of the n-conduction-type carbon nanostructure.

According to the above aspect of the present invention, the diode has a Schottky junction formed between the n-conduction-type carbon nanostructure, and the first electrode formed on the upper end surface of the n-conduction-type carbon nanostructure.

The present invention provides, in claim 8, a diode as described in claim 7, wherein the n-conduction-type carbon nanostructure is formed on an electrically conductive region, and the diode further comprises a second electrode connected to the electrically conductive region.

No particular limitation is imposed on the electrically conductive region, and it may be, for example, a metal region, or an electrically conductive semiconductor region doped with an impurity.

The present invention provides, in claim 9, a diode as described in claim 8, wherein the electrically conductive region is formed of an n-type semiconductor.

The present invention provides, in claim 10, a diode as described in any one of claims 1 to 9, wherein the n-conduction-type carbon nanostructure is formed through plasma CVD in an atmosphere containing a nitrogen plasma.

According to the above aspect of the present invention, plasma CVD is carried out in an atmosphere containing a nitrogen plasma for forming the n-conduction-type carbon nanostructure.

The present invention provides, in claim 11, a diode as described in any one of claims 1 to 10, wherein the carbon nanostructure is carbon nanowalls or carbon nanotubes.

The present invention provides, in claim 12, a photovoltaic device comprising a p-conduction-type semiconductor, and an n-conduction-type carbon nanostructure grown on the p-conduction-type semiconductor.

According to the above aspect of the present invention, a pn junction is formed in the photovoltaic device between the p-conduction-type semiconductor and the n-conduction-type carbon nanostructure.

The p-conduction-type semiconductor may be made of a desired semiconductor such as silicon, a group III-V compound semiconductor (e.g., GaAs), or a group III nitride semiconductor. The p-conduction-type semiconductor may be in a bulk form, or a p-conduction-type region formed through doping of a partial region of a substrate with an acceptor impurity.

The present invention provides, in claim 13, a photovoltaic device as described above, which further comprises a first electrode connected to the upper end surface of the n-conduction-type carbon nanostructure, and a second electrode connected to the p-conduction-type semiconductor. The first electrode may be connected directly to the n-conduction-type carbon nanostructure, or an electrically conductive layer may be provided therebetween. The second electrode may be connected directly to the p-conduction-type semiconductor, or an electrically conductive layer may be provided therebetween.

The present invention provides, in claim 14, a photovoltaic device comprising an n-conduction-type carbon nanostructure, and a p-conduction-type carbon nanostructure formed on a surface of the n-conduction-type carbon nanostructure.

According to the above aspect of the present invention, a pn junction is formed in the photovoltaic device between the n-conduction-type carbon nanostructure, and the p-conduction-type carbon nanostructure formed on a surface of the n-conduction-type carbon nanostructure.

In the characteristic pn junction of the present invention, the n-conduction-type carbon nanostructure may be supported by any member.

When the n-conduction-type carbon nanostructure is grown on a substrate, no particular limitation is imposed on the substrate, and a desired substrate (e.g., a semiconductor substrate, a glass substrate, or a metal substrate) may be employed. The substrate employed may have insulating or electrically conductive property. The n-conduction-type carbon nanostructure may be formed on an electrically conductive diffusion region on a substrate, or may be formed on an electrically conductive material (e.g., a metal) provided on an insulating substrate.

The present invention provides, in claim 15, a photovoltaic device as described in claim 14, wherein the n-conduction-type carbon nanostructure is formed on a substrate, and the photovoltaic device further comprises a first electrode connected to the upper end surface of the p-conduction-type carbon nanostructure, and a second electrode connected to the n-conduction-type carbon nanostructure.

According to the above aspect of the present invention, the n-conduction-type carbon nanostructure is grown on a substrate; the first electrode is provided on the p-conduction-type carbon nanostructure; and the second electrode is connected to the n-conduction-type carbon nanostructure.

Similar to the case of claim 13 according to the present invention, the first electrode may be connected directly to the p-conduction-type carbon nanostructure, or an electrically conductive layer may be provided therebetween; and the second electrode may be connected directly to the n-conduction-type semiconductor, or an electrically conductive layer may be provided therebetween.

The present invention provides, in claim 16, a photovoltaic device as described in claim 15, wherein the substrate is the n-conduction-type semiconductor, and the second electrode is formed on the substrate.

The present invention provides, in claim 17, a photovoltaic device as described in any one of claims 12 to 16, wherein the p-conduction-type carbon nanostructure is a carbon nanostructure having a surface terminated by fluorine atoms.

According to the above aspect of the present invention, the p-conduction-type carbon nanostructure is formed, with terminating carbon atoms of a surface of a carbon nanostructure by fluorine atoms.

The present invention provides, in claim 18, a photovoltaic device comprising an n-conduction-type carbon nanostructure, and a first electrode formed on the upper end surface of the n-conduction-type carbon nanostructure.

According to the above aspect of the present invention, the photovoltaic device has a Schottky junction formed between the n-conduction-type carbon nanostructure, and the first electrode formed on the upper end surface of the n-conduction-type carbon nanostructure.

The present invention provides, in claim 19, a photovoltaic device as described in claim 18, wherein the n-conduction-type carbon nanostructure is formed on an electrically conductive region, and the photovoltaic device further comprises a second electrode connected to the electrically conductive region.

No particular limitation is imposed on the electrically conductive region, and it may be, for example, a metal region, or an electrically conductive semiconductor region doped with an impurity.

The present invention provides, in claim 20, a photovoltaic device as described in claim 19, wherein the electrically conductive region is formed of an n-type semiconductor.

The present invention provides, in claim 21, a photovoltaic device as described in any one of claims 12 to 20, wherein the n-conduction-type carbon nanostructure is formed through plasma CVD in an atmosphere containing a nitrogen plasma.

According to the above aspect of the present invention, plasma CVD is carried out in an atmosphere containing a nitrogen plasma for forming the n-conduction-type carbon nanostructure.

The present invention provides, in claim 22, photovoltaic device as described in any one of claims 12 to 21, wherein the carbon nanostructure is carbon nanowalls or carbon nanotubes.

As used herein, the term “carbon nanowall(s)” is used to refer to a carbon nanostructure which extends two-dimensionally. Carbon nanowalls are formed of graphene sheets which extend two-dimensionally and which are provided upright on the surface of a base, and each nanowall is formed of a single layer or multiple layers. As used herein, the expression “extend two-dimensionally” refers to the case where the lengths of a carbon nanowall in longitudinal and lateral directions are sufficiently greater than the thickness (width) thereof. The carbon nanowall may be formed of multiple layers, a single layer, or a pair of layers (with a space provided therebetween). The upper surfaces of carbon nanowalls may be covered so that cavities are provided therebetween. For example, carbon nanowalls have a thickness of about 0.05 to about 30 nm, and a longitudinal or lateral length of about 100 nm to about 10 μm. In general, a carbon nanowall is expressed as “extending two-dimensionally,” since the lengths of the carbon nanowall in longitudinal and lateral directions are much greater than the width thereof, and thus can be controlled.

Typically, carbon nanowalls produced through the aforementioned production method are a carbon nanostructure formed of upright walls extending from the surface of a base in generally the same direction. Fullerenes (e.g., C60) can be regarded as zero-dimensional carbon nanostructures, and carbon nanotubes can be regarded as one-dimensional carbon nanostructures. The carbon nanotube may have a single-layer structure, or a multi-layer structure formed of two or more layers.

### EFFECTS OF THE INVENTION

A structure as described in claim 1, 2, 3, 4, or 5 was found to exhibit rectification property. Therefore, according to the present invention, the structure can serves as an electronic device exhibiting rectification property; i.e., a diode. The structure may also serve as a capacitor under application of reverse bias voltage.

According to claim 6, a p-conduction-type carbon nanostructure can be formed, with terminating a surface of a carbon nanostructure by fluorine.

A structure as described in claim 7, 8, or 9 was found to exhibit rectification property. Since a Schottky junction is formed between the first electrode and the n-conduction-type carbon nanostructure, a rectification property can be attained.

According to claim 10 of the present invention, an n-conduction-type carbon nanostructure can be produced through plasma CVD in an atmosphere containing a nitrogen plasma.

A device having a structure as described in claim 11, 13, 14, 15, or 16 was found to exhibit rectification property. Therefore, since the device has a band gap, the device can serve as a photovoltaic device under irradiation with light. The device of the present invention serves as a solar cell when used in a forward direction, and also serves as a photodetector when used in a backward direction.

According to claim 17, a p-conduction-type carbon nanostructure is formed, with terminating a surface of a carbon nanostructure by fluorine.

A structure as described in claim 18, 19, or 20 was found to exhibit rectification property. Since a Schottky junction is formed between the first electrode and the n-conduction-type carbon nanostructure, rectification property can be obtained, and photovoltaic power can be generated through irradiation with light.

According to claim 21 of the present invention, an n-conduction-type carbon nanostructure can be produced through plasma CVD in an atmosphere containing a nitrogen plasma.

### BRIEF DESCRIPTION OF THE DRAWINGS

FIG. 1 is a schematic representation of an apparatus for producing carbon nanowalls employed in a diode of the present invention.

FIG. 2 is a side view of the structure of a diode of Example 1 of the present invention.

FIG. 3 is a graph showing data corresponding to rectification property of the diode of Example 1.

FIG. 4 is a side view of the structure of a diode of Example 2 of the present invention.

FIG. 5 is a graph showing data corresponding to rectification property of the diode of Example 2.

FIG. 6 is a side view of the structure of a diode of Example 3 of the present invention.

FIG. 7 is a graph showing data corresponding to rectification property of the diode of Example 3.

FIG. 8 is a graph showing data corresponding to rectification property of a diode of Comparative Example.

FIG. 9 shows side views of the structures diodes of other embodiments.

FIG. 10 is a side view of the structure of a photovoltaic device of Example 4 of the present invention.

FIG. 11 is a graph showing data corresponding to rectification property of the photovoltaic device of Example 4.

FIG. 12 is a graph showing data corresponding to rectification property of the photovoltaic device of Example 4 under irradiation with light.

FIG. 13 is a side view of the structure of a photovoltaic device of Example 5 of the present invention.

FIG. 14 is a graph showing data corresponding to rectification property of the photovoltaic device of Example 5.

FIG. 15 is a side view of the structure of a photovoltaic device of Example 6 of the present invention.

FIG. 16 is a graph showing data corresponding to rectification property of the photovoltaic device of Example 6.

FIG. 17 is a graph showing data corresponding to rectification property of a photovoltaic device of Comparative Example.

FIG. 18 shows side views of the structures of photovoltaic devices of other embodiments.

### DESCRIPTION OF REFERENCE NUMERALS

2: Carbon nanowall production apparatus
70: p-Conduction-type silicon substrate
80: n-Conduction-type silicon substrate
73, 81, 91: N-conduction-type carbon nanowalls
82: P-conduction-type carbon nanowalls
370: P-conduction-type silicon substrate
480: N-conduction-type silicon substrate
373, 481, 591: N-conduction-type carbon nanowalls
482: P-conduction-type carbon nanowalls
375, 485, 595: First electrode
376, 486, 596: Second electrode

### BEST MODES FOR CARRYING OUT THE INVENTION

Preferred embodiments of the present invention will next be described in detail. Technical matters that are necessary for carrying out the present invention but are not specifically referred to herein should be understood to be matters of design choice that those skilled in the art are recognized on the basis of conventional techniques. The present invention can be carried out on the basis of technical matters disclosed herein and techniques generally known to those skilled in the art.

Various raw materials containing at least carbon as a constituent element may be employed for producing a carbon nanostructure (e.g., carbon nanowalls or carbon nanotubes). The element which can constitute such a raw material together with carbon is one or more elements selected from among, for example, hydrogen, fluorine, chlorine, bromine, nitrogen, and oxygen. Examples of preferred raw materials include a raw material virtually consisting of carbon and hydrogen, a raw material virtually consisting of carbon and fluorine, and a raw material virtually consisting of carbon, hydrogen, and fluorine. For example, a saturated or unsaturated hydrocarbon (e.g., CH₄), a fluorocarbon (e.g., C₂F₆), or a fluorohydrocarbon (e.g., CHF₃) is preferably employed. A raw material having a linear, branched, or cyclic molecular structure may be employed. Generally, a raw material which is in a gaseous state at ambient temperature and ambient pressure (i.e., a raw material gas) is preferably employed. Only a single raw material may be employed, or two or more raw materials may be employed in arbitrary proportions. The type of a raw material and the composition of raw materials may be unchanged throughout production stages (e.g., a growth process) of carbon nanowalls, or may be varied depending on the production stages. The type a raw material and the composition of raw materials, the method for supplying the raw material(s), or other conditions may be appropriately determined in consideration of structural features and/or properties (e.g., electrical properties) of carbon nanowalls of interest.

Production of carbon nanowalls does not require a metal catalyst. Meanwhile, when carbon nanotubes are produced, preferably, nanoparticles of a metal (e.g., Co or Co—Ti) are deposited on a substrate on which carbon nanotubes are formed.

Radicals injected into a plasma atmosphere preferably contain at least hydrogen radicals (i.e., atomic hydrogen, hereinafter may be referred to as “H radicals”). Preferably, H radicals are generated through decomposition of a radical source material containing at least hydrogen as a constituent element, and the thus-generated H radicals are injected into a plasma atmosphere. Such a radical source material is particularly preferably hydrogen gas (H₂). The radical source material employed is preferably a material containing at least hydrogen as a constituent element. Preferably, a radical source material which is in a gaseous state at ambient temperature and ambient pressure (i.e., a radical source gas) is employed. The radical source material employed may be a material which can generate H radicals through decomposition (e.g., a hydrocarbon such as CH₄). Only a single radical source material may be employed, or two or more radical source materials may be employed in arbitrary proportions.

Particularly, carbon nanowalls or carbon nanotubes can be effectively produced through supplying H radicals as a solo radical species. Conceivably, formation of carbon nanotubes is facilitated in the presence of an appropriate amount of OH radicals or O radicals.

Preferably, at least one of the conditions for producing carbon nanowalls or carbon nanotubes is controlled on the basis of the concentration of at least one type of radicals in a reaction chamber (e.g., the concentration of at least one type of radicals selected from among carbon radicals, hydrogen radicals, and fluorine radicals). Examples of the production condition which may be controlled on the basis of such a radical concentration include the amount of a raw material(s) supplied, conditions required for forming a plasma-state raw material(s) (severity of plasma formation conditions), and the amount of radicals (typically, H radicals) injected. Preferably, such production conditions are feedback-controlled on the basis of the aforementioned radical concentration. According to such a production method, carbon nanowalls or carbon nanotubes exhibiting intended structural features and/or properties can be effectively produced.

In the production method, preferably, radicals are injected into an atmosphere containing a plasma-state raw material(s). Thus, the raw material plasma and radicals (typically, H radicals) are mixed together. Specifically, radicals (H radicals) are present at high concentration in the raw material plasma atmosphere. Carbon nanowalls are formed (grown) on a base through deposition of carbon thereon from a region containing the raw material plasma and radicals. Examples of the base which may be employed include a base in which at least a region on which carbon nanowalls are formed is made of Si, SiO₂, Si₃N₄, GaAs, Al₂O₃, or a similar material. When an insulating substrate is employed, in order to form an electrode with respect to carbon nanowalls, a portion of the substrate is converted into an electrically conductive region through doping of an impurity, or a metal wiring layer on which carbon nanowalls are formed is provided on a surface of the substrate. The entirety of the base employed may be made of any of the aforementioned materials. According to the aforementioned production method, carbon nanowalls can be formed directly on a surface of the aforementioned base without using a catalyst such as nickel-iron. However, a catalyst such as Ni, Fe, Co, Pd, or Pt (typically, a transition metal catalyst) may be employed. For example, a thin film (e.g., a film having a thickness of about 1 to about 10 nm) of any of the aforementioned catalysts may be formed on a surface of the aforementioned base, and carbon nanowalls may be formed on the catalyst thin film. When carbon nanotubes are formed on a substrate, nanoparticles of such a catalyst are deposited on the substrate. No particular limitation is imposed on the outer shape of the base employed. Typically, a plate-like base (substrate) is employed.

### Example 1

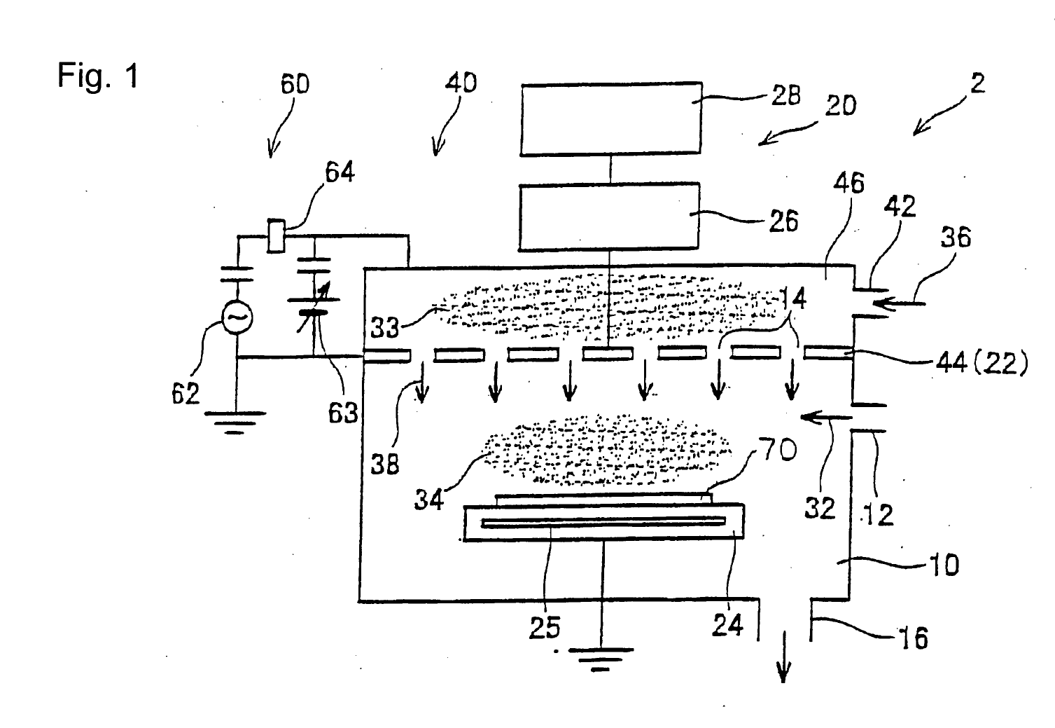

FIG. 1 shows a configuration of an apparatus for producing carbon nanowalls (carbon nanostructure) employed in the present invention. An apparatus 1 includes a reaction chamber 10; plasma discharge means 20 for forming a plasma in the reaction chamber 10; and radical supply means 40 connected to the reaction chamber 10. The plasma discharge means 20 is configured so as to serve as a parallel plate-type capacitively coupled plasma (CCP) formation mechanism. The plasma discharge means 20 employed in Example 1 includes a first electrode 22 and a second electrode 24, each of which has a generally disk shape. These electrodes 22 and 24 are disposed in the reaction chamber 10 so as to be generally parallel to each other. Typically, the first electrode 22 is disposed above the second electrode 24.

The first electrode (cathode) 22 is connected to a power supply 28 via a matching network 26. The power supply 28 and the matching network 26 can generate at least one of RF waves (e.g., 13.56 MHz), UHF waves (e.g., 500 MHz), VHF waves (e.g., 27 MHz, 40 MHz, 60 MHz, 100 MHz, and 150 MHz), and microwaves (e.g., 2.45 GHz). In Example 1, the power supply and the matching network are configured so that at least RF waves can be generated.

The second electrode (anode) 24 is disposed in the reaction chamber 10 so as to be away from the first electrode 22. The distance between the electrodes 22 and 24 may be, for example, about 0.5 to about 10 cm. In Example 1, the distance is about 5 cm. The second electrode 24 is grounded. For production of carbon nanowalls, a substrate (base) 5 is placed on the second electrode 24. For example, the substrate 70 is placed on the top surface of the second electrode 24 so that a surface of the base 5 on which carbon nanowalls are produced is exposed (faced to the first electrode 22). The second electrode 24 includes therein a heater 25 (e.g., a carbon heater) serving as base temperature control means. If necessary, the temperature of the substrate 70 may be controlled by operating the heater 25.

The reaction chamber 10 includes a raw material inlet 12 through which a raw material (raw material gas) can be supplied from a non-illustrated supply source. In a preferred embodiment, the inlet 12 is provided so that a raw material gas can be supplied between the first electrode (upper electrode) 22 and the second electrode (lower electrode) 24. The reaction chamber 10 also includes radical inlets 14 through which radicals can be introduced from the below-described radical supply means 40. In a preferred embodiment, the inlets 14 are provided so that radicals can be introduced between the first electrode 22 and the second electrode 24. The reaction chamber 10 also includes a discharge outlet 16. The discharge outlet 16 is connected to, for example, a non-illustrated vacuum pump serving as pressure control means (pressure reducing means) for controlling the pressure in the reaction chamber 10. In a preferred embodiment, the discharge outlet 16 is provided below the second electrode 24.

The radical supply means 40 includes a plasma formation chamber 46 provided above the reaction chamber 10. The plasma formation chamber 46 is separated from the reaction chamber 10 by a partition 44 which is provided so as to face the surface of the substrate 70 on which carbon nanowalls are formed. The partition 44 is connected to the power supply 28 via the matching network 26. That is, in Example 1, the partition 44 also serves as the first electrode 22. The apparatus 2 includes high frequency application means 60 for applying RF waves, VHF waves, or UHF waves to a space between the partition 44 and the walls of the plasma formation chamber 46. Thus, a plasma 33 can be formed from a radical source gas 36. In the high frequency application means 60 shown in FIG. 1, reference numeral 62 denotes an AC power supply, 63 a bias power supply, and 64 a filter.

Ions generated from the plasma 33 are electrically neutralized at the partition 44, to thereby yield radicals 38. In this case, percent neutralization may be appropriately increased through application of an electric field to the partition 44. Energy may be applied to the neutral radicals. Numerous through-holes are distributed in the partition 44. The radicals 38 are introduced through these through-holes (serving as the numerous radical inlets 14) into the reaction chamber 10 and diffused as is therein, and then the radicals 38 are injected into a plasma atmosphere 34. As shown in FIG. 1, the inlets 14 are provided in a direction parallel to the top surface of the substrate 70 (the surface facing the first electrode 22; i.e., the surface on which carbon nanowalls are formed). With this configuration of the apparatus 2, the radicals 38 can be more uniformly diffused in a wider region in the reaction chamber 10. Therefore, carbon nanowalls can be effectively formed on a wider region (area) of the substrate 70. In addition, carbon nanowalls having more uniform structural features, properties, etc. can be formed at any portions of the substrate surface. According to Example 1, one or more of these effects can be achieved.

The partition 44 may be coated with a material exhibiting high catalytic performance (e.g., Pt), or may be made of such a material itself. When an electric field is applied between the partition 44 having such a structure and the plasma atmosphere 34 (typically, a negative bias is applied to the partition 44), ions contained in the plasma atmosphere 34 are accelerated, and the partition 44 is sputtered by the ions, whereby atoms (e.g., Pt) or clusters exhibiting catalytic performance can be injected into the plasma atmosphere 34. A carbon nanowall formation process employs the radicals 38 (typically, H radicals) injected from the plasma formation chamber 46, radicals and/or ions containing at least carbon, the radicals and/or ions being generated in the plasma atmosphere 34, and atoms or clusters exhibiting catalytic performance which are generated through the aforementioned sputtering of the partition 44 and injected into the plasma atmosphere 34. Thus, atoms, clusters, or fine particles exhibiting catalytic performance can be deposited in the interiors and/or on the surfaces of the thus-formed carbon nanowalls. The carbon nanowalls containing such atoms, clusters, or fine particles are applicable to, for example, a material for an electrode of a fuel cell, since the carbon nanowalls can exhibit high catalytic performance.

Carbon nanowalls were formed by means of the above-described apparatus 1.

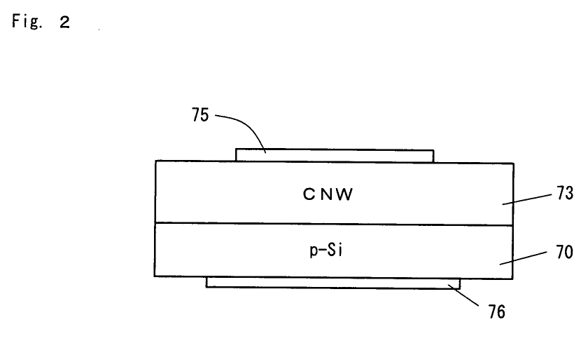

As shown in FIG. 2, a p-type silicon substrate 70 (0.5 mm) was employed. N-type carbon nanowalls 73 were grown on the substrate 70. In Example 1, C₂F₆ was employed as the raw material gas 32. Hydrogen gas (H₂) and nitrogen gas (N₂) were employed as the radical source gas 36. The surface of the substrate on which carbon nanowalls are formed contains substantially no catalyst (e.g., metal catalyst).

The silicon substrate 70 was placed on the second electrode 24 so that the (100) plane of the substrate 70 faced the first electrode 22. The raw material gas 32 (i.e., C₂F₆) was supplied through the raw material inlet 12 into the reaction chamber 10, and the radical source gas 36 (i.e., hydrogen gas and nitrogen gas) was supplied through a radical source inlet 42. Gas in the reaction chamber 10 was discharged through the discharge outlet 16. The supply amount (flow rate) of the raw material gas 32 and the radical source gas 36, and gas discharge conditions were controlled so that, in the reaction chamber 10, the C₂F₆ partial pressure was about 20 mTorr, the H₂ partial pressure was about 80 mTorr, and the total pressure was about 100 mTorr (C₂F₆: 50 sccm, H₂: 100 sccm, N₂: 20 sccm).

While the raw material gas 32 was supplied under the aforementioned conditions, an RF power (13.56 MHz, 100 W) was applied from the power supply 28 to the first electrode 22, and RF waves were applied to the raw material gas 32 (C₂F₆) contained in the reaction chamber 10. Thus, a plasma of the raw material gas 32 was formed, whereby the plasma atmosphere 34 was provided between the first electrode 22 and the second electrode 24. While the radical source gas 36 was supplied under the aforementioned conditions, an RF power (13.56 MHz, 50 W) was applied from a power supply 58 to a coil 52, and RF waves were applied to the radical source gas 36 (H₂ and N₂) contained in the radical formation chamber 40. The thus-generated H radicals and N radicals were introduced through the radical inlets 14 into the reaction chamber 10. Thus, carbon nanowalls were grown (formed) on the (100) plane of the silicon substrate 70. In Example 1, carbon nanowalls were grown for two hours. During this growth period, the temperature of the substrate 70 was maintained at about 600° C. by using, as necessary, the heater 25 or a non-illustrated cooling apparatus. The growth time was three hours. The thus-grown carbon nanowalls 73, 74 were found to have a height of 530 nm and a thickness of 30 nm.

As described above, the n-conduction-type carbon nanowalls 73 were formed. Subsequently, gold was deposited on the end surfaces of the n-conduction-type carbon nanowalls 73 through EB deposition, to thereby form a first electrode 75. Meanwhile, gold was deposited on the bottom surface of the p-conduction-type silicon substrate 70 through EB deposition, to thereby form a second electrode 76. Thus, there was formed a diode having a pn junction between the p-conduction-type silicon substrate 70 and the n-conduction-type carbon nanowalls 73.

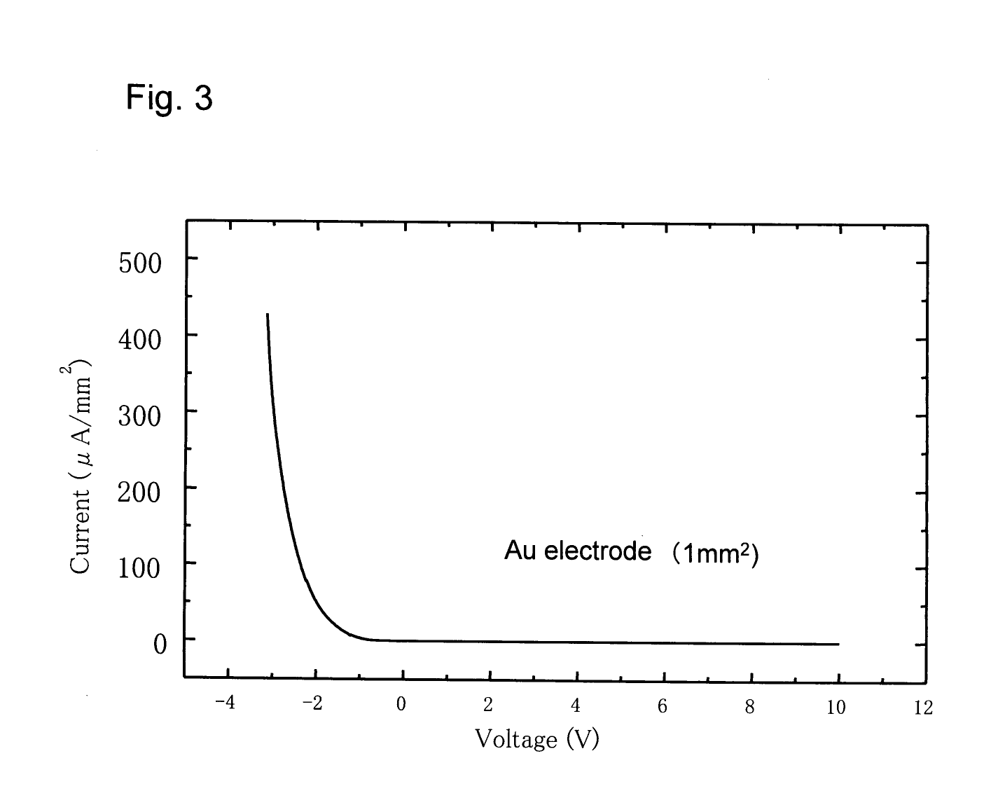

Voltage-current characteristics of the thus-formed diode were measured. The results are shown in FIG. 3. In FIG. 3, the positive direction of voltage refers to such a direction that the electric potential of the first electrode 73 is higher than that of the second electrode 76. In the case where voltage was applied between these electrodes so that the electric potential of the second electrode 76 was positive, and the electric potential of the first electrode 73 was negative, current was found to exponentially increase in response to an increase in voltage. In contrast, in the case where voltage was applied between these electrodes so that the electric potential of the first electrode 73 was positive, and the electric potential of the second electrode 76 was negative, even when voltage was increased, no current flowed. Thus, the diode of Example 1 exhibited typical rectification property.

### Example 2

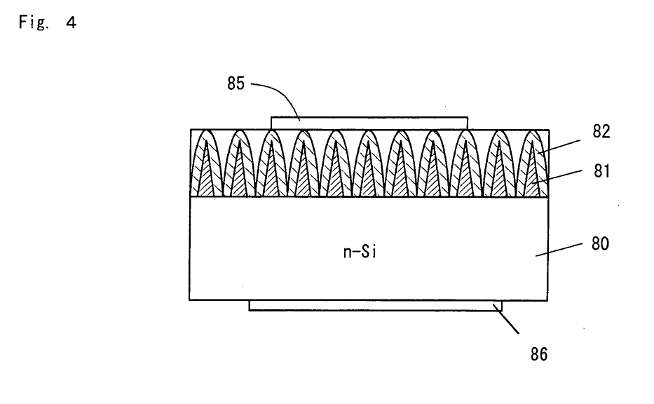

As shown in FIG. 4, n-conduction-type carbon nanowalls 81 were formed on an n-conduction-type silicon substrate 80 in a manner similar to that described in Example 1. Subsequently, supply of the radical source gas 36 (i.e., N₂ gas and H₂ gas) was stopped, and only C₂F₆ gas was subjected to electric discharge. Thus, p-conduction-type carbon nanowalls 82 were grown so as to cover the surfaces of the n-conduction-type carbon nanowalls 81.

Subsequently, gold was deposited on the end surfaces of the p-conduction-type carbon nanowalls 82 through EB deposition, to thereby form a first electrode 85. Meanwhile, gold was deposited on the bottom surface of the n-conduction-type silicon substrate 80 through EB deposition, to thereby form a second electrode 86. Thus, there was formed a diode having a pn junction between the n-conduction-type carbon nanowalls 81 and the p-conduction-type carbon nanowalls 82.

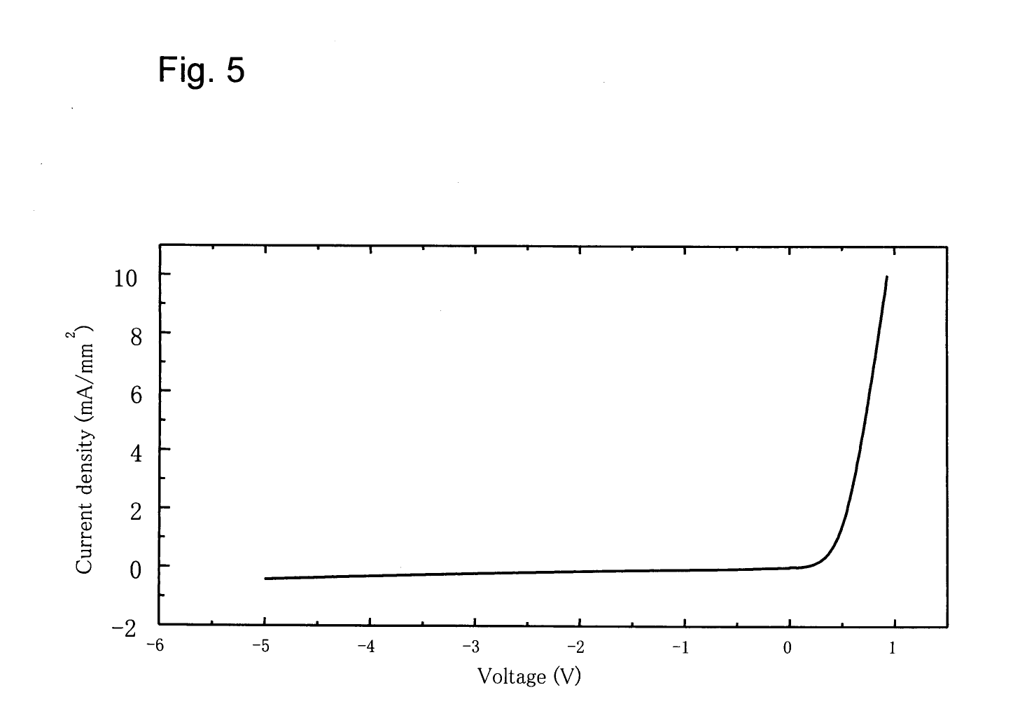

Voltage-current characteristics of the thus-formed diode were measured. The results are shown in FIG. 5. In FIG. 5, the positive direction of voltage refers to such a direction that the electric potential of the first electrode 85 is higher than that of the second electrode 86. In the case where voltage was applied between these electrodes so that the electric potential of the first electrode 85 was positive, and the electric potential of the second electrode 86 was negative, current was found to exponentially increase in response to an increase in voltage. In contrast, in the case where voltage was applied between these electrodes so that the electric potential of the second electrode 86 was positive, and the electric potential of the first electrode 85 was negative, even when voltage was increased, no current flowed. Thus, the diode of Example 2 exhibited typical rectification property.

### Example 3

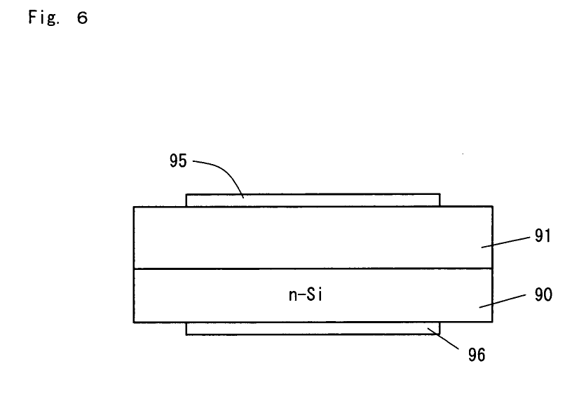

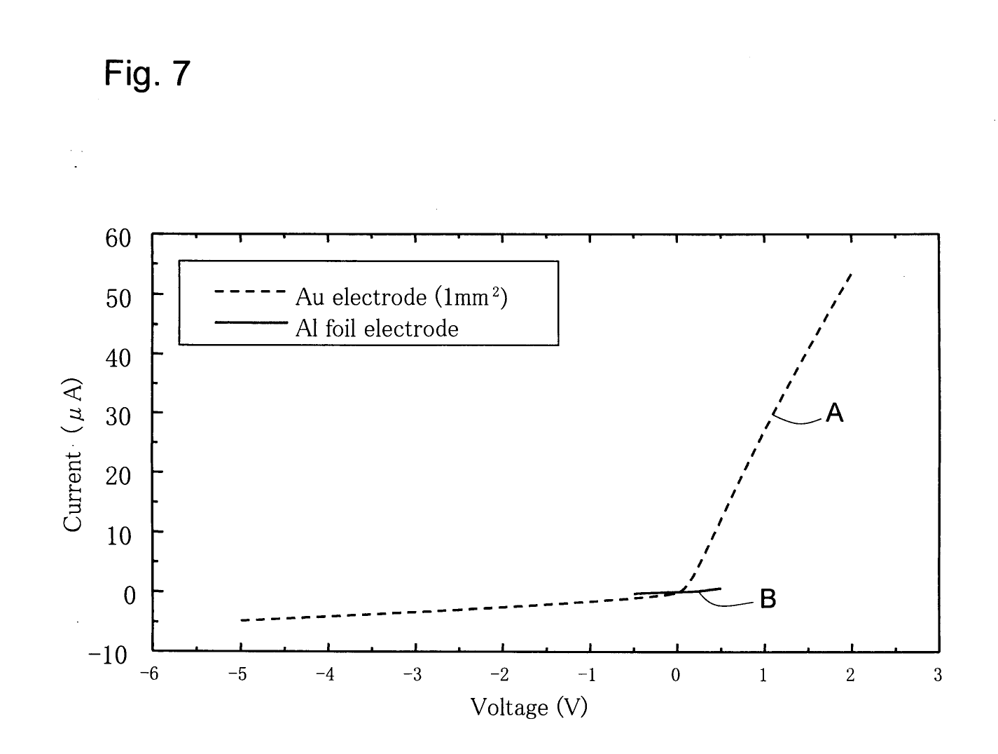

As shown in FIG. 6, n-conduction-type carbon nanowalls 91 were formed on an n-conduction-type silicon substrate 90 in a manner similar to that described in Example 1. Subsequently, gold was deposited on the end surfaces of the n-conduction-type carbon nanowalls 91 through EB deposition, to thereby form a first electrode 95. Meanwhile, gold was deposited on the bottom surface of the n-conduction-type silicon substrate 90 through EB deposition, to thereby form a second electrode 96. Thus, a Schottky barrier was formed at the interface between the n-conduction-type carbon nanowalls 91 and the first electrode 95 made of gold. There was formed a diode having this Schottky barrier, in which the first electrode 95 serves as a positive electrode, and the second electrode 96 serves as a negative electrode. Voltage-current characteristics of the diode were measured. The results are shown in FIG. 7 (curve A).

In FIG. 7, the positive direction of voltage refers to such a direction that the electric potential of the first electrode 95 is higher than that of the second electrode 96. In the case where voltage was applied between these electrodes so that the electric potential of the first electrode 95 was positive, and the electric potential of the second electrode 96 was negative, current was found to exponentially increase in response to an increase in voltage. In contrast, in the case where voltage was applied between these electrodes so that the electric potential of the second electrode 96 was positive, and the electric potential of the first electrode 95 was negative, even when voltage was increased, no considerable increase in current was observed. Thus, the diode of Example 3 exhibited typical rectification property.

The first electrode 95 was made of aluminum instead of gold, and voltage-current characteristics of the thus-formed diode were measured. As shown by curve B in FIG. 7, the diode did not exhibit rectification property. Aluminum, which has a work function lower than that of gold, exhibits better ohmic property. In general, a metal having lower work function exhibits better ohmic property with respect to an n-type semiconductor. Therefore, as is clear from data shown in FIG. 7, the carbon nanowalls 91 have n-type conductivity.

### Comparative Example

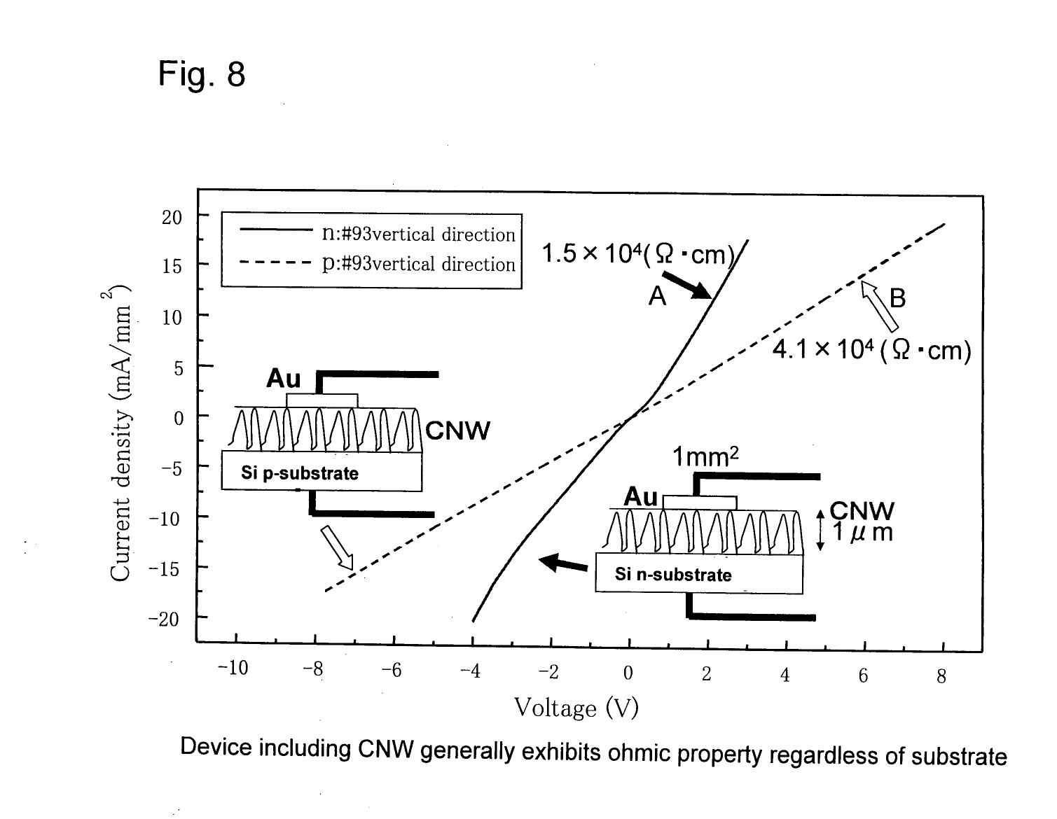

Carbon nanowalls were grown on an n-type or p-type silicon substrate in the same manner as in Example 1, except that nitrogen radicals were not introduced. FIG. 8 shows voltage-current characteristics of the thus-formed devices. Curve A in FIG. 8 corresponds to voltage-current characteristics of a device including carbon nanowalls grown on the n-type silicon substrate, whereas curve B in FIG. 8 corresponds to voltage-current characteristics of a device including carbon nanowalls grown on the p-type silicon substrate. These devices exhibited high resistivity; i.e., the former device was found to have a resistivity of 1.5×10⁴ Ω·cm, and the latter device was found to have a resistivity of 4.1×10⁴ Ω·cm.

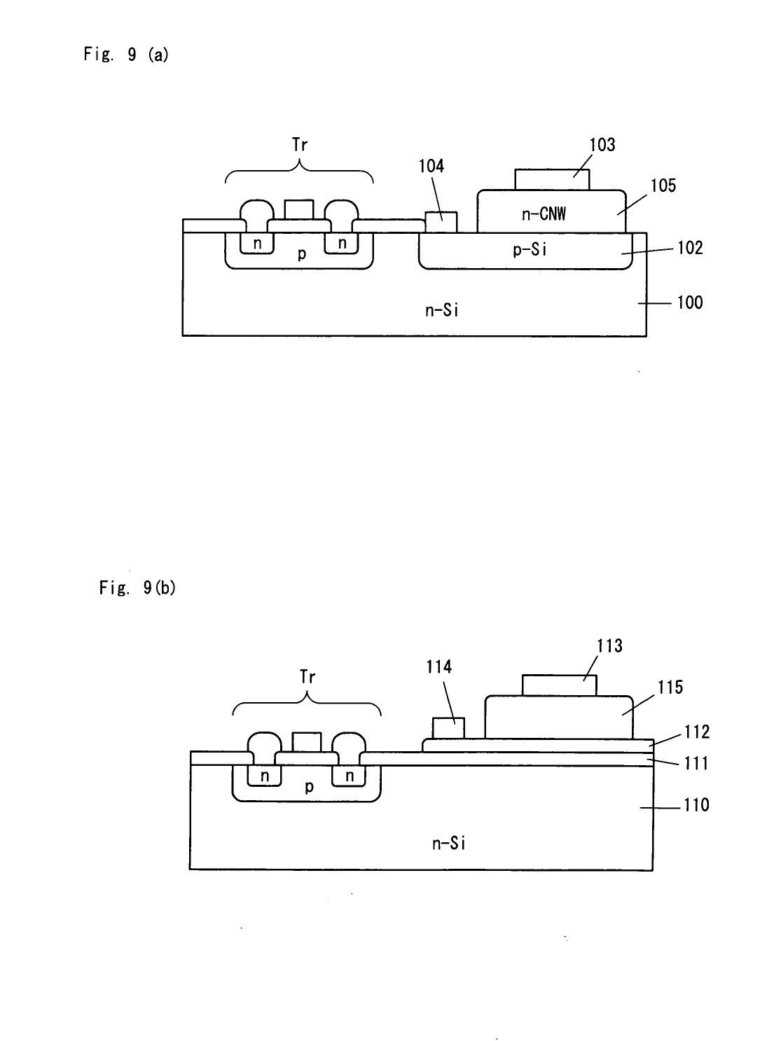

As shown in FIG. 9(a), a diode may be formed through the following procedure: a surface of an n-silicon substrate 100 is doped with an acceptor, to thereby form a p-type region 102, and n-conduction-type carbon nanowalls 105 are formed on the p-type region 102. In this case, a first electrode 103 is formed on the upper end surfaces of the n-conduction-type carbon nanowalls 105, and a second electrode 104 is formed on the p-type region 102.

Alternatively, as shown in FIG. 9(b), a diode 115 having a structure described in Example 2 (i.e., a pn junction between n-conduction-type carbon nanowalls and p-conduction-type carbon nanowalls formed on the surfaces thereof) may be formed on a metal wiring layer 112 formed on a silicon oxide film 111 provided on an n-silicon substrate 100. A first electrode 113 may be formed on the p-conduction-type carbon nanowalls, and a second electrode 114 may be formed on the metal wiring layer 112. As shown in FIG. 9(a) or 9(b), a transistor Tr may be formed on the silicon substrate 110 so that the transistor Tr and a diode of any of the aforementioned Examples together form an integrated circuit.

Although diodes including carbon nanowalls have been described in the aforementioned Examples, conceivably, a diode including carbon nanotubes can be formed in a manner similar to that described above. Although N atoms were employed for forming an n-conduction-type carbon nanostructure (e.g., n-conduction-type carbon nanowalls) as described above, a group V element other than N (e.g., P, As, Sb, or Bi) or a group VI element (e.g., O, S, or Se) may be employed. As described above, F was employed for forming p-conduction-type carbon nanowalls. However, a halogen atom other than F, a group III element (e.g., B, Al, Ga, In, or Tl), or a group II element (e.g., Be, Mg, Ca, Sr, or Ba) may be employed. Such a carbon nanostructure is produced through plasma CVD employing an organometallic gas containing any of these elements.

### Example 4

A photovoltaic device of the present invention is produced by means of the same production apparatus as described in Example 1 (i.e., the apparatus shown in FIG. 1).

Carbon nanowalls were formed by means of the above-described apparatus 1.

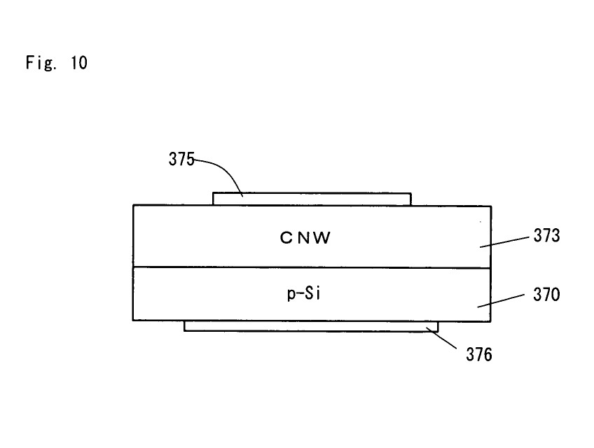

As shown in FIG. 10, a p-type silicon substrate 370 (0.5 mm) was employed. N-type carbon nanowalls 373 were grown on the substrate 370. In Example 4, C₂F₆ was employed as the raw material gas 32. Hydrogen gas (H₂) and nitrogen gas (N₂) were employed as the radical source gas 36. The surface of the substrate on which carbon nanowalls are formed contains substantially no catalyst (e.g., metal catalyst).

The silicon substrate 370 was placed on the second electrode 24 so that the (100) plane of the substrate 370 faced the first electrode 22. The raw material gas 32 (i.e., C₂F₆) was supplied through the raw material inlet 12 into the reaction chamber 10, and the radical source gas 36 (i.e., hydrogen gas and nitrogen gas) was supplied through a radical source inlet 42. Gas in the reaction chamber 10 was discharged through the discharge outlet 16. The supply amount (flow rate) of the raw material gas 32 and the radical source gas 36, and gas discharge conditions were controlled so that, in the reaction chamber 10, the C₂F₆ partial pressure was about 20 mTorr, the H₂ partial pressure was about 80 mTorr, and the total pressure was about 100 mTorr (C₂F₆: 50 sccm, H₂: 100 sccm, N₂: 20 sccm).

While the raw material gas 32 was supplied under the aforementioned conditions, an RF power (13.56 MHz, 100 W) was applied from the power supply 28 to the first electrode 22, and RF waves were applied to the raw material gas 32 (C₂F₆) contained in the reaction chamber 10. Thus, a plasma of the raw material gas 32 was formed, whereby the plasma atmosphere 34 was provided between the first electrode 22 and the second electrode 24. While the radical source gas 36 was supplied under the aforementioned conditions, an RF power (13.56 MHz, 50 W) was applied from the power supply 58 to the coil 52, and RF waves were applied to the radical source gas 36 (H₂ and N₂) contained in the radical formation chamber 40. The thus-generated H radicals and N radicals were introduced through the radical inlets 14 into the reaction chamber 10. Thus, carbon nanowalls were grown (formed) on the (100) plane of the silicon substrate 370. In Example 4, carbon nanowalls were grown for two hours. During this growth period, the temperature of the substrate 370 was maintained at about 550° C. by using, as necessary, the heater 25 or a non-illustrated cooling apparatus. The growth time was three hours. The thus-grown carbon nanowalls 73, 74 were found to have a height of 530 nm and a thickness of 30 nm.

As described above, the n-conduction-type carbon nanowalls 373 were formed. Subsequently, gold was deposited on the end surfaces of the n-conduction-type carbon nanowalls 373 through EB deposition, to thereby form a first electrode 375. Meanwhile, gold was deposited on the bottom surface of the p-conduction-type silicon substrate 370 through EB deposition, to thereby form a second electrode 376. Thus, there was formed a photovoltaic device having a pn junction between the p-conduction-type silicon substrate 370 and the n-conduction-type carbon nanowalls 373.

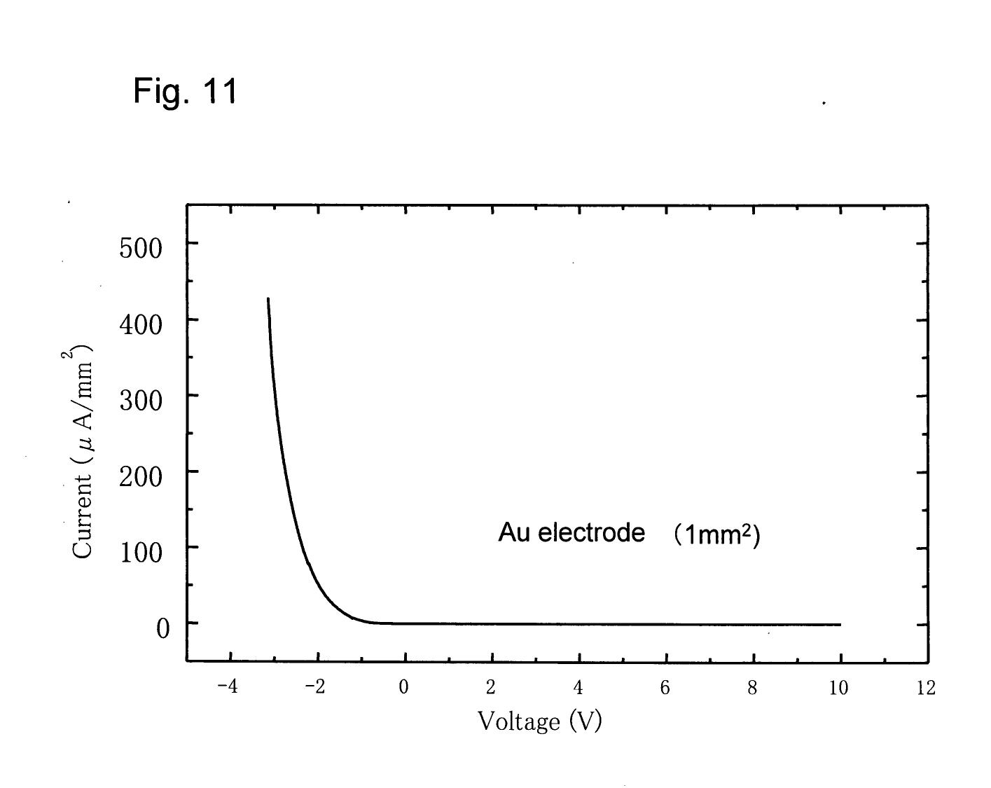

Voltage-current characteristics of the thus-formed photovoltaic device were measured. The results are shown in FIG. 11. In FIG. 11, the positive direction of voltage refers to such a direction that the electric potential of the first electrode 373 is higher than that of the second electrode 376. In the case where voltage was applied between these electrodes so that the electric potential of the second electrode 376 was positive, and the electric potential of the first electrode 373 was negative, current was found to exponentially increase in response to an increase in voltage. In contrast, in the case where voltage was applied between these electrodes so that the electric potential of the first electrode 373 was positive, and the electric potential of the second electrode 376 was negative, even when voltage was increased, no current flowed. Thus, the photovoltaic device of Embodiment 4 exhibited typical rectification property.

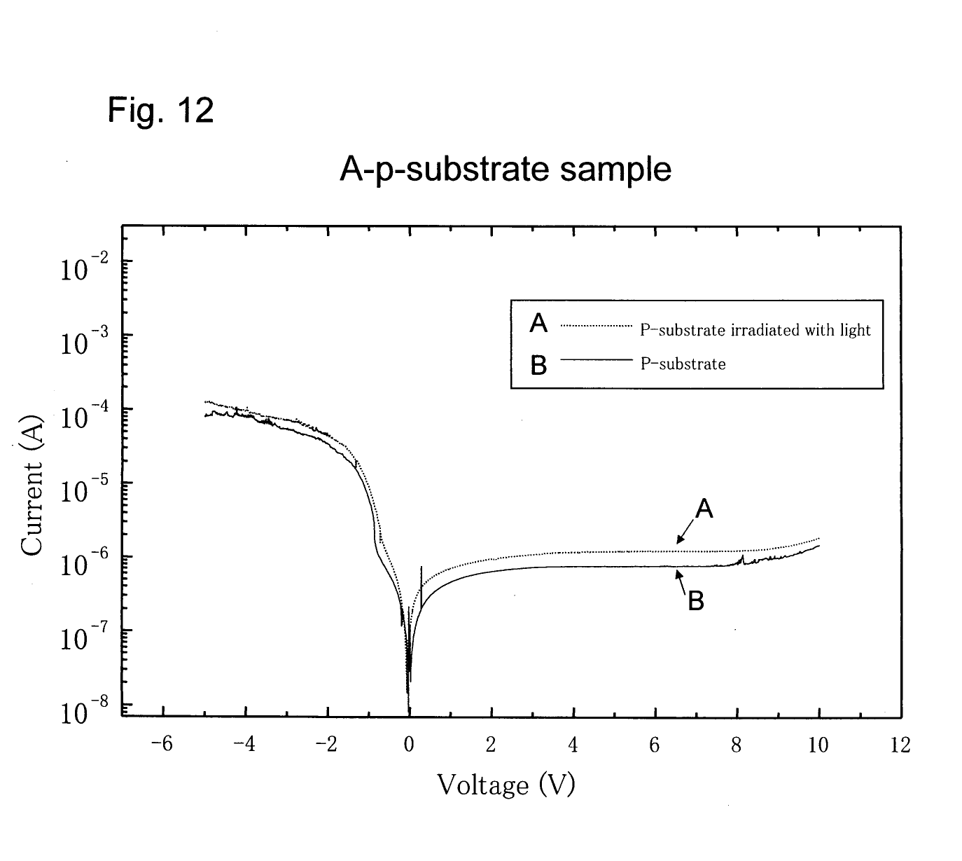

The photovoltaic device was irradiated with visible light. FIG. 12 shows voltage-current characteristics of the photovoltaic device as measured under irradiation with visible light. In FIG. 12, curve A corresponds to voltage-current characteristics of the photovoltaic device irradiated with visible light, whereas curve B corresponds to voltage-current characteristics of the photovoltaic device which is not irradiated with visible light (i.e., curve B corresponds to the measurement data shown in FIG. 11). As is clear from FIG. 12, an increase in current is observed at the same voltage under application of reverse bias; i.e., the device functions as a photovoltaic device.

### Example 5

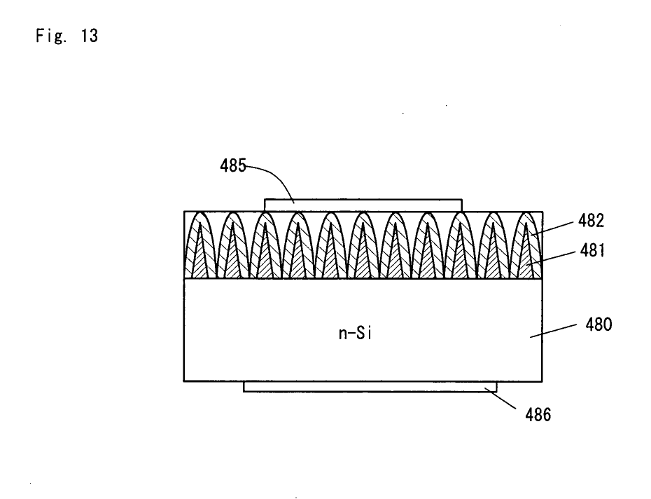

As shown in FIG. 13, n-conduction-type carbon nanowalls 481 were formed on an n-conduction-type silicon substrate 480 in a manner similar to that described in Example 3. Subsequently, supply of the radical source gas 36 (i.e., N₂ gas and H₂ gas) was stopped, and only C₂F₆ gas was subjected to electric discharge. Thus, p-conduction-type carbon nanowalls 482 were grown so as to cover the surfaces of the n-conduction-type carbon nanowalls 481.

Subsequently, gold was deposited on the end surfaces of the p-conduction-type carbon nanowalls 482 through EB deposition, to thereby form a first electrode 485. Meanwhile, gold was deposited on the bottom surface of the n-conduction-type silicon substrate 480 through EB deposition, to thereby form a second electrode 486. Thus, there was formed a photovoltaic device having a pn junction between the p-conduction-type carbon nanowalls 482 and the n-conduction-type carbon nanowalls 481.

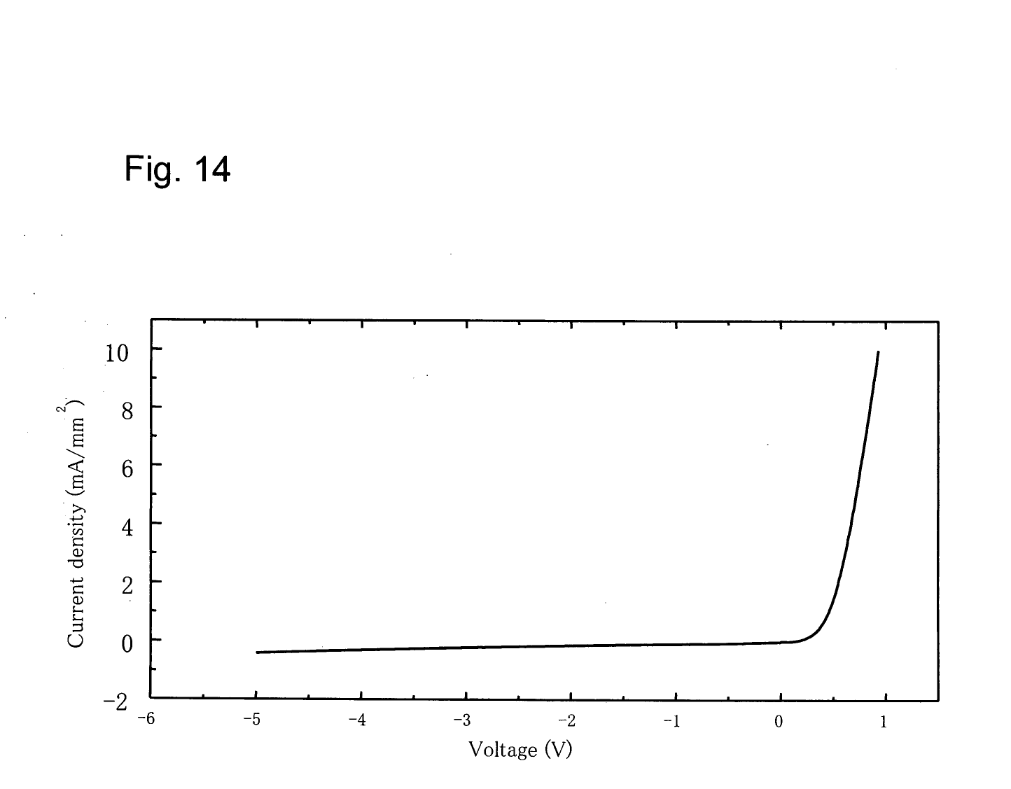

Voltage-current characteristics of the thus-formed photovoltaic device were measured. The results are shown in FIG. 14. In FIG. 14, the positive direction of voltage refers to such a direction that the electric potential of the first electrode 485 is higher than that of the second electrode 486. In the case where voltage was applied between these electrodes so that the electric potential of the first electrode 485 was positive, and the electric potential of the second electrode 486 was negative, current was found to exponentially increase in response to an increase in voltage. In contrast, in the case where voltage was applied between these electrodes so that the electric potential of the second electrode 486 was positive, and the electric potential of the first electrode 485 was negative, even when voltage was increased, no current flowed. Thus, the photovoltaic device of Example 5 exhibited typical rectification property. This rectification property indicates that the photovoltaic device has a band gap, and thus generates photovoltaic power under irradiation with light.

### Example 6

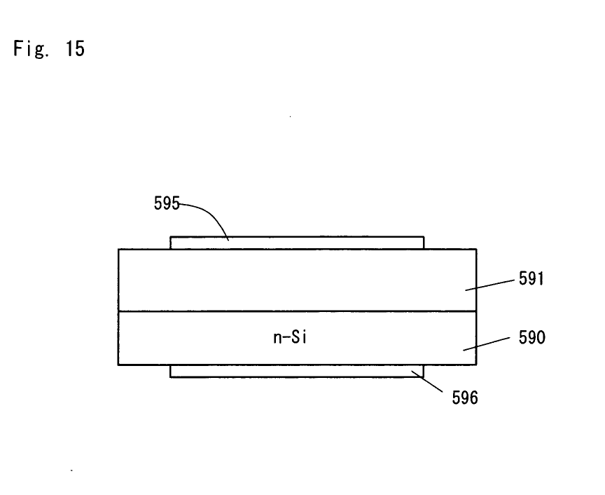

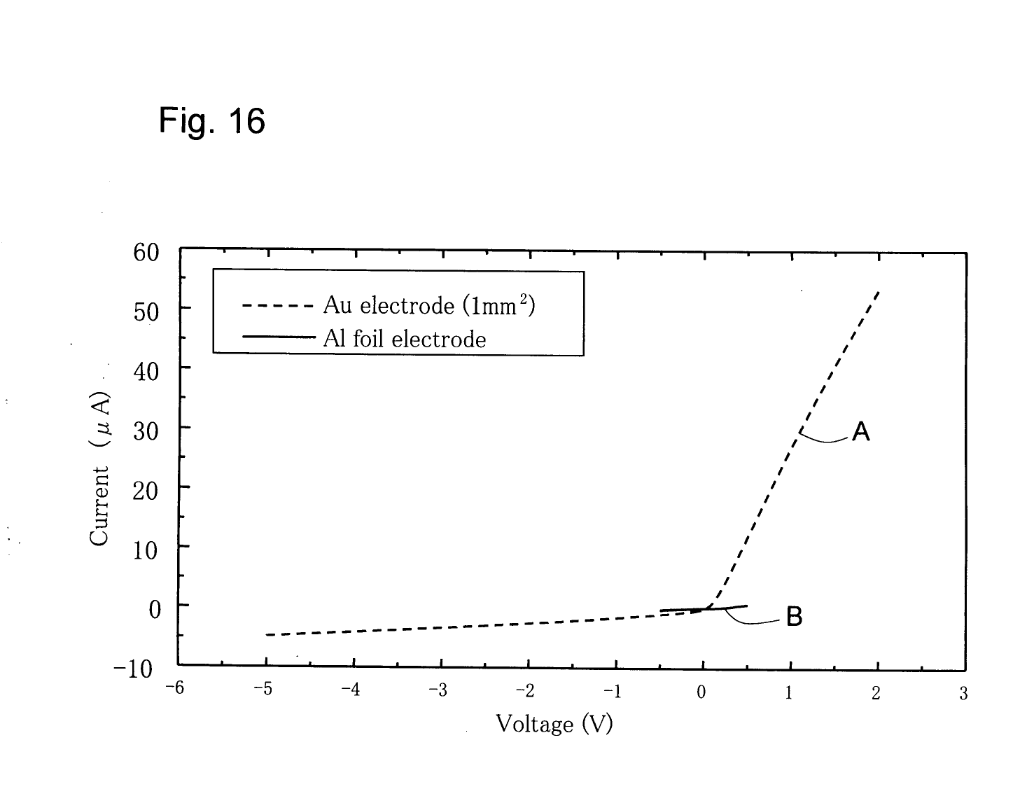

As shown in FIG. 15, n-conduction-type carbon nanowalls 591 were formed on an n-conduction-type silicon substrate 590 in a manner similar to that described in Example 4. Subsequently, gold was deposited on the end surfaces of the n-conduction-type carbon nanowalls 591 through EB deposition, to thereby form a first electrode 595. Meanwhile, gold was deposited on the bottom surface of the n-conduction-type silicon substrate 590 through EB deposition, to thereby form a second electrode 596. Thus, a Schottky barrier was formed at the interface between the n-conduction-type carbon nanowalls 591 and the first electrode 595 made of gold. There was formed a photovoltaic device having this Schottky barrier, in which the first electrode 595 serves as a positive electrode, and the second electrode 596 serves as a negative electrode. Voltage-current characteristics of the photovoltaic device were measured. The results are shown in FIG. 16 (curve A).

In FIG. 16, the positive direction of voltage refers to such a direction that the electric potential of the first electrode 595 is higher than that of the second electrode 596. In the case where voltage was applied between these electrodes so that the electric potential of the first electrode 595 was positive, and the electric potential of the second electrode 596 was negative, current was found to exponentially increase in response to an increase in voltage. In contrast, in the case where voltage was applied between these electrodes so that the electric potential of the second electrode 596 was positive, and the electric potential of the first electrode 595 was negative, even when voltage was increased, no considerable increase in current was observed. Thus, the photovoltaic device of Embodiment 6 exhibited typical rectification property. This indicates that the photovoltaic device has a Schottky barrier, and the present invention realizes a photovoltaic device having a Schottky barrier.

The first electrode 595 was made of aluminum instead of gold, and voltage-current characteristics of the thus-formed photovoltaic device were measured. As shown by curve B in FIG. 16, the photovoltaic device did not exhibit rectification property. Aluminum, which has a work function lower than that of gold, exhibits better ohmic property. In general, a metal having lower work function exhibits better ohmic property with respect to an n-type semiconductor. Therefore, as is clear from data shown in FIG. 16, the carbon nanowalls 591 have n-type conductivity.

### Comparative Example

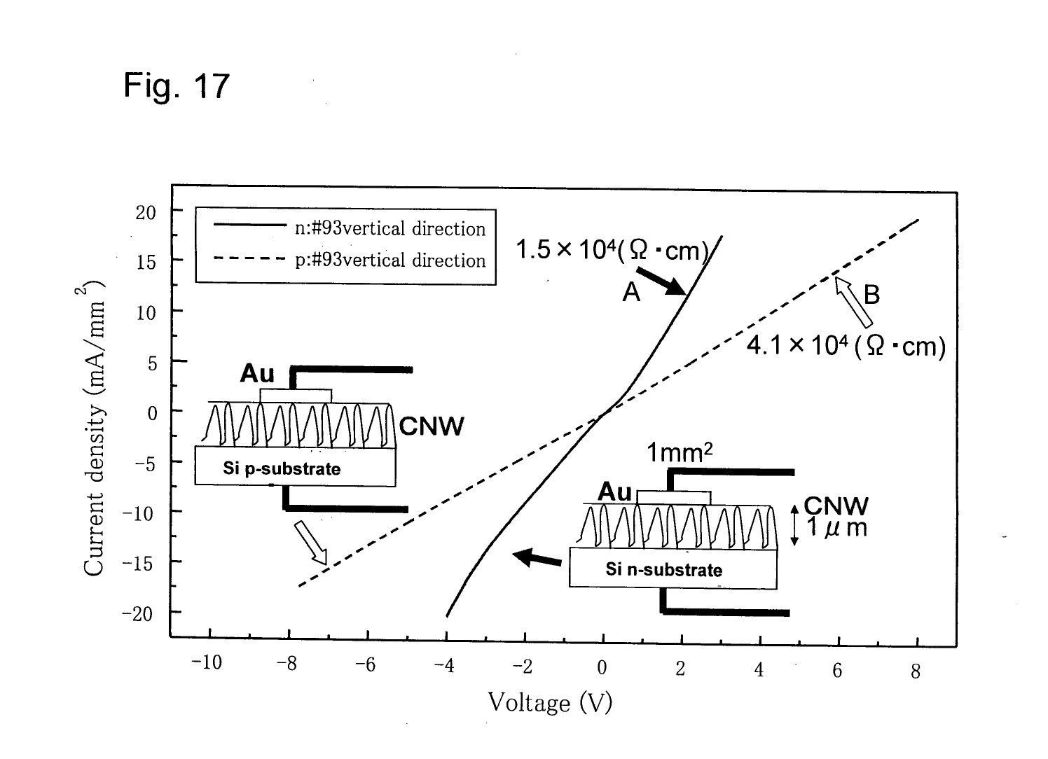

Carbon nanowalls were grown on an n-type or p-type silicon substrate in the same manner as in Example 4, except that nitrogen radicals were not introduced. FIG. 17 shows voltage-current characteristics of the thus-formed devices. Curve A in FIG. 17 corresponds to voltage-current characteristics of a device including carbon nanowalls grown on the n-type silicon substrate, whereas curve B in FIG. 17 corresponds to voltage-current characteristics of a device including carbon nanowalls grown on the p-type silicon substrate. These devices exhibited high resistivity; i.e., the former device was found to have a resistivity of 1.5×10⁴ Ω·cm, and the latter device was found to have a resistivity of 4.1×10⁴ Ω·cm.

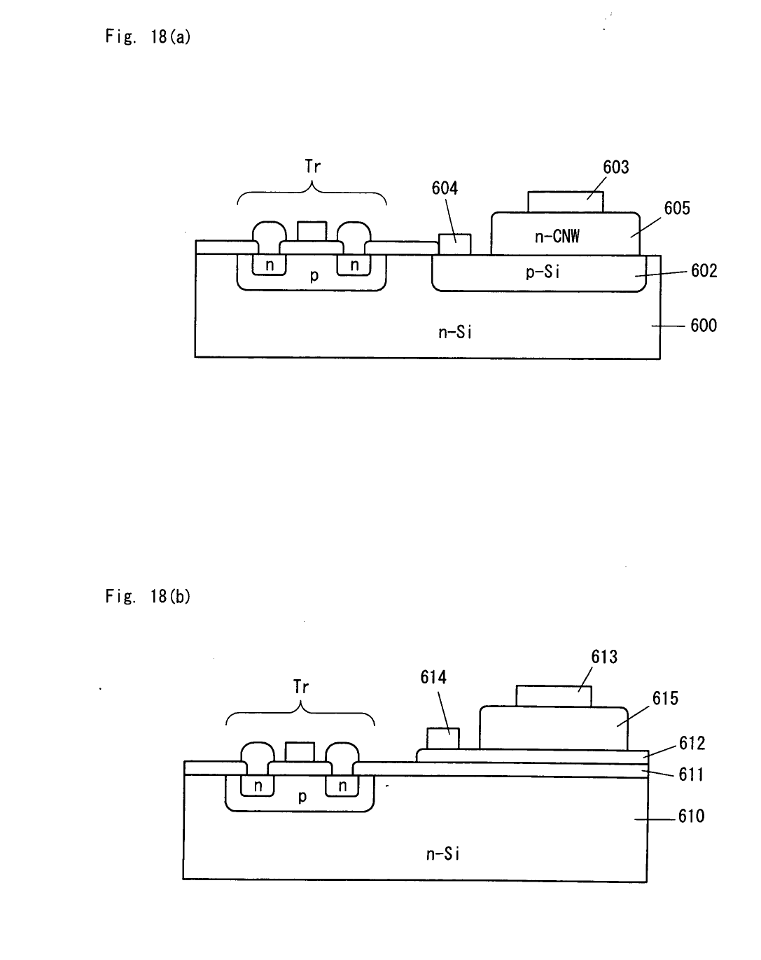

As shown in FIG. 18(a), a photovoltaic device may be formed through the following procedure: a surface of an n-silicon substrate 600 is doped with an acceptor, to thereby form a p-type region 602, and n-conduction-type carbon nanowalls 605 are formed on the p-type region 602. In this case, a first electrode 603 is formed on the upper end surfaces of the n-conduction-type carbon nanowalls 605, and a second electrode 604 is formed on the p-type region 602.

Alternatively, as shown in FIG. 18(b), a photovoltaic device 615 having a structure described in Example 4 (i.e., a pn junction between n-conduction-type carbon nanowalls and p-conduction-type carbon nanowalls formed on the surfaces thereof) may be formed on a metal wiring layer 612 formed on a silicon oxide film 611 provided on an n-silicon substrate 600. A first electrode 613 may be formed on the p-conduction-type carbon nanowalls, and a second electrode 614 may be formed on the metal wiring layer 612. As shown in FIG. 16(a) or 16(b), a transistor Tr may be formed on the silicon substrate 610 so that the transistor Tr and a photovoltaic device of any of the aforementioned Examples together form an integrated circuit.

Although photovoltaic devices including carbon nanowalls have been described in the aforementioned Examples, conceivably, a photovoltaic device including carbon nanotubes can be formed in a manner similar to that described above. Although N atoms were employed for forming an n-conduction-type carbon nanostructure (e.g., n-conduction-type carbon nanowalls) as described above, a group V element other than N (e.g., P, As, Sb, or Bi) or a group VI element (e.g., O, S, or Se) may be employed. As described above, F was employed for forming p-conduction-type carbon nanowalls. However, a halogen atom other than F, a group III element (e.g., B, Al, Ga, In, or Tl), or a group II element (e.g., Be, Mg, Ca, Sr, or Ba) may be employed. Such a carbon nanostructure is produced through plasma CVD employing an organometallic gas containing any of these elements.

### INDUSTRIAL APPLICABILITY

The present invention provides a diode or photovoltaic device having a novel structure. In general, the diode or photovoltaic device can be employed in electronic circuits and solar cells.

1. A diode comprising a p-conduction-type semiconductor, and an n-conduction-type carbon nanostructure grown on the p-conduction-type semiconductor.

2. A diode as described in claim 1, which further comprises a first electrode connected to the upper end surface of the n-conduction-type carbon nanostructure, and a second electrode connected to the p-conduction-type semiconductor.

3. A diode comprising an n-conduction-type carbon nanostructure, and a p-conduction-type carbon nanostructure formed on a surface of the n-conduction-type carbon nanostructure.

4. A diode as described in claim 3, wherein the n-conduction-type carbon nanostructure is formed on a substrate, and the diode further comprises a first electrode connected to the upper end surface of the p-conduction-type carbon nanostructure, and a second electrode connected to the n-conduction-type carbon nanostructure.

5. A diode as described in claim 4, wherein the substrate comprises the n-conduction-type semiconductor, and the second electrode is formed on the substrate.

6. A diode as described in claim 3, wherein the p-conduction-type carbon nanostructure comprises a carbon nanostructure having a surface terminated by fluorine atoms.

7. A diode comprising an n-conduction-type carbon nanostructure, and a first electrode formed on the upper end surface of the n-conduction-type carbon nanostructure.

8. A diode as described in claim 7, wherein the n-conduction-type carbon nanostructure is formed on an electrically conductive region, and the diode further comprises a second electrode connected to the electrically conductive region.

9. A diode as described in claim 8, wherein the electrically conductive region comprises an n-type semiconductor.

10. A diode as described in claim 1, wherein the n-conduction-type carbon nanostructure is formed through plasma CVD in an atmosphere containing a nitrogen plasma.

11. A diode as described in claim 1, wherein the carbon nanostructure comprises carbon nanowalls or carbon nanotubes.

12. A photovoltaic device comprising a p-conduction-type semiconductor, and an n-conduction-type carbon nanostructure grown on the p-conduction-type semiconductor.

13. A photovoltaic device as described in claim 12, which further comprises a first electrode connected to the upper end surface of the n-conduction-type carbon nanostructure, and a second electrode connected to the p-conduction-type semiconductor.

14. A photovoltaic device comprising an n-conduction-type carbon nanostructure, and a p-conduction-type carbon nanostructure formed on a surface of the n-conduction-type carbon nanostructure.

15. A photovoltaic device as described in claim 14, wherein the n-conduction-type carbon nanostructure is formed on a substrate, and the photovoltaic device further comprises a first electrode connected to the upper end surface of the p-conduction-type carbon nanostructure, and a second electrode connected to the n-conduction-type carbon nanostructure.

16. A photovoltaic device as described in claim 15, wherein the substrate is the n-conduction-type semiconductor, and the second electrode is formed on the substrate.

17. A photovoltaic device as described in claim 14, wherein the p-conduction-type carbon nanostructure comprises a carbon nanostructure having a surface terminated by fluorine atoms.

18. A photovoltaic device comprising an n-conduction-type carbon nanostructure, and a first electrode formed on the upper end surface of the n-conduction-type carbon nanostructure.

19. A photovoltaic device as described in claim 18, wherein the n-conduction-type carbon nanostructure is formed on an electrically conductive region, and the photovoltaic device further comprises a second electrode connected to the electrically conductive region.

20. A photovoltaic device as described in claim 19, wherein the electrically conductive region comprises an n-type semiconductor.

21. A photovoltaic device as described in claim 12, wherein the n-conduction-type carbon nanostructure is formed through plasma CVD in an atmosphere containing a nitrogen plasma.

22. A photovoltaic device as described in claim 12, wherein the carbon nanostructure comprises carbon nanowalls or carbon nanotubes.
